(19) United States
(12) Patent Application Publication
(10) Pub. No.: US 2006/0077409 A1
(43) Pub. Date: Apr. 13, 2006

(54) Color conversion method, color conversion system, color conversion program product, printing control method, printing control system, printing control program product, and color conversion table

(76) Inventor: Jun Hoshii, Nagano-ken (JP)

Correspondence Address: MARTINE PENILLA & GENCARELLA, LLP, 710 LAKEWAY DRIVE, SUITE 200, SUNNYVALE, CA, 94085, US

(21) Appl. No.: 11/240,973

(22) Filed: Sep. 30, 2005

(30) Foreign Application Priority Data
Sep. 30, 2004 (JP) 2004-289144

(51) Int. Cl. G03F 3/08

(52) U.S. Cl. 358/1.9; 358/518; 358/3.06

(57) ABSTRACT

The relationship of correspondence between first color image data and second color image data is established for each of lattice points in a predetermined color space. A characteristic color contained in the first color image data is identified based on a predetermined criterion. The positions of lattice points falling within the domain in the color space expressing the identified characteristic color are shifted so as to narrow the spacing between adjoining ones of the lattice points. The relationship of correspondence is established for each of the shifted lattice points. A point of coordinates represented by the first color image data is allocated to any of lattice points surrounding the point of coordinates according to a predetermined rule. Improvement in granularity of dots and reductions in the number of calculations and an amount of data are accomplished.

### BACKGROUND OF THE INVENTION

1. Field of the Invention

The present invention relates to a color conversion method, a color conversion system, a color conversion program product, a printing control method, a printing control system, a printing control program product, and a color conversion table which make it possible to convert first color image data employed in first image equipment into second color image data employed in second image equipment.

2. Description of the Related Art

Assume that a printer is used to form an image according to input image data defined in a color space employed in input equipment such as a scanner or a digital camera (for example, color image data including three components, that is, red (R) data, green (G) data, and blue (B) data). In this case, the input image data is converted into image data defined in a color space employed in the printer (for example, a CMY color space defining cyan (C) data, magenta (M) data, and yellow (Y) data (as well as light cyan (lc) data, light magenta (lm) data, and black (K) data)). The conversion is generally achieved using a color conversion lookup table (LUT) that specifies for each of lattice points in a color space the relationship of correspondence between color image data employed in first image equipment and color image data employed in second image equipment.

Known as a conversion technique employing the color conversion lookup table is such that unconverted image data representing coordinates that indicates a certain point is forcibly allocated to any of surrounding lattice points according to a predetermined rule (hereinafter referred to as preconversion), and color image data employed in the second image equipment and associated with the allocated lattice point is adopted as converted image data.

The present inventor has disclosed an image processing system that uses encoding coefficients to convert color data from RGB data to CMYK data by referencing a color conversion lookup table so that converted gray levels falling within the domain expressing a highlight will become larger. After the color conversion has been completed, when CMYK data is converted into dot data representing large dots and small dots, smaller gray levels than input gray levels are provided (refer to, for example, PCT No. WO2002/032113).

When conversion includes preconversion, once image data is allocated to any of surrounding lattice points, conversion is achieved. The processing time is much shorter than the processing time required for conversion in which image data items associated with the surrounding lattice points are read to perform interpolation such as so-called tetrahedral interpolation. On the other hand, compared with the conversion employing interpolation, the conversion including preconversion is inferior in conversional precision signifying how faithfully source colors are reproduced. As for a printout, the granularity of dots tends to be discerned (poor granularity).

In order to solve the foregoing problems, the number of lattice points associated with items of a color conversion lookup table may be greatly increased in order to narrow the spacing between adjoining ones of the lattice points. Otherwise, the technique employing interpolation may be adopted as a conversion technique. However, this still poses a problem in that the number of arithmetic and logical operations required for constructing the color conversion lookup table or for conversion is large and a large area in a memory that is a resource is consumed.

Although the technique described in the above patent publication proves effective in expressing a fine change of gray levels using small dots. However, since conversion is basically accompanied by interpolation, the degradation in granularity of dots in a printout which is likely to derive from conversion including preconversion is not overcome.

### SUMMARY OF THE INVENTION

The present invention addresses the foregoing problems. An object of the present invention is to provide a color conversion method, a color conversion system, a color conversion program, a printing control method, a printing control system, a printing control program, and a color conversion table which make it possible to produce image data, which expresses an image of an excellent granularity, as a result of conversion by performing a small number of arithmetic and logical operations using a small memory area.

In efforts to accomplish the above object, there is provided a color conversion method according to the one aspect of the present invention in which: the relationship of correspondence between first color image data employed in first image equipment and second color image data employed in second image equipment is established for each of lattice points in a predetermined color space; and the established relationships of correspondence are referenced so as to convert the first color image data into the second color image data.

Herein, at a characteristic color recognition step, a characteristic color contained in an image expressed by the received first color image data is identified based on a predetermined criterion. Thereafter, at a relationship-of-correspondence establishment step, the positions of lattice points falling within the domain in the color space expressing the characteristic color are shifted so as to narrow the spacing between adjoining ones of the lattice points. Moreover, the relationship of correspondence is established for each of the shifted lattice points. At an image data conversion step, a point of coordinates represented by first color image data is allocated to any of lattice points surrounding the point of coordinates according to a predetermined rule, and second color image data associated with the allocated lattice point is read in order to thus achieve the conversion.

According to the aspect of the present invention, a characteristic color exhibiting the characteristic of an image expressed by received first color image data is identified. The relationship of correspondence between first color image data and second color image data is established for each of lattice points that fall into a color domain expressing the characteristic color and that are rearranged so as to narrow the spacing between adjoining ones of the lattice points. The thus established relationships of correspondence are referenced in order to execute conversion including preconversion. The precision in converting in a color domain that expresses the characteristic color and similar colors is therefore improved. Consequently, the markedness in the granulation of dots in a printout produced based on image data expressing the characteristic color or colors similar to the characteristic color can be prevented. Moreover, since the number of lattice points is not increased, the number of calculations to be performed in order to establish the relationships of correspondence may be small and a memory area needed to save the relationships of correspondence may be small.

In another aspect of the present invention, at the characteristic color recognition step, an image expressed by received first color image data is checked to see if it contains a color falling within a predetermined color domain. If the presence of the color falling within the predetermined color domain is recognized, the predetermined color falling within the color domain may be recognized as the characteristic color of the image expressed by the first color image data. In other words, a color to be recognized as a characteristic color is predefined, and the image expressed by the first color image data is checked to see if it contains the color or a similar color. If a color that is a color of dots that should appear little granularly in a printout is designated as a characteristic color, the precision in converting image data that contains data expressing the color improves. Thus, the degradation in the granularity in a printout can be effectively prevented.

Various colors are conceivable as a characteristic color. For example, at the characteristic color recognition step, an image expressed by received first color image data may be checked to see if it contains a color falling within a predetermined flesh color domain. The flesh color is the color of dots that should especially appear little granularly in a photographic image of a human body. When the image expressed by the first color image data contains the flesh color or a similar color, the flesh color or a similar color is adopted as a characteristic color. Consequently, the precision in converting a color domain that expresses the flesh color or a similar color improves. Thus, a high-quality image can be provided with the degradation of the granularity in the flesh color of a similar color in a printout prevented.

In another aspect of the present invention, at the characteristic color recognition step, a color highly frequently used in an image expressed by received first color image data may be identified and recognized as a characteristic color of the image expressed by the first color image data. Since the characteristic color is a color representative of the image expressed by the first color image data, a color frequently used in the image can be said to be the characteristic color. If a color highly frequently used in an image is adopted as the characteristic color, the precision in converting a color domain that expresses the highly frequently used color or a similar color improves. Consequently, the markedness in the granulation of dots can be suppressed all over a printout.

To be more specific, at the characteristic color recognition step, a frequency distribution is produced using each of components of first color image data, that is, each of color data items constituting first color image data. A highly frequently used color is identified based on the distribution. In other words, assuming that the first color image data includes plural color data items, if a frequency distribution is produced using each of the color data items, a color highly frequently used in an image can be readily identified based on the frequency distributions.

Furthermore, at the characteristic color recognition step, a color expressed by substantial medians detected in frequency distributions produced using respective color data items constituting first color image data may be adopted as the highly frequently used color. The frequency distribution of values represented by each color data item is usually plotted mountainously on a predetermined gray scale and often has a peak substantially at the center position. When a color identified with substantial medians of frequency distributions produced using respective color data items is adopted as a characteristic color, the characteristic color is a color representative of an image. Herein, what is referred to as the substantial median may be any of various statistical values acquired from a frequency distribution, and may refer to a means, a median, or the highest frequency.

Technological ideas concerning the present invention have been described as the aspects of the present invention. The technological ideas may be regarded as the constituent features of a system in accordance with the present invention. Namely, a color conversion system in accordance with the present invention offers the same operation and advantages as those mentioned above. Moreover, a procedure in accordance with the present invention may be executed by a computer. Namely, the present invention may be applied as a program to the computer. A color conversion program product in accordance with the present invention therefore offers the same operation and advantages as the aforesaid ones.

Moreover, the aforesaid aspects may be adapted to the method or program. Any of storage media can be used to provide the program. For example, a magnetic recording medium or a magneto-optical recording medium will do. The same applies to any recording medium that may be developed in the future. Moreover, a color conversion system having part thereof realized with software and the other part thereof realized with hardware is not inconsistent with the spirit of the present invention. The present invention encompasses a system part of which is recorded in a recording medium and read from it if necessary. Furthermore, a replication step of producing a primary replica or a secondary replica is encompassed by the present invention.

The aforesaid color conversion method will prove valuable when being implemented in an actual printing control procedure.

A printing control method in which the relationship of correspondence between first color image data employed in first image equipment and second color image data employed in second image equipment is established for each of lattice points in a predetermined color space, and the established relationships of correspondence are referenced in order to thus convert the first color image data into the second color image data includes: a characteristic color recognition step of identifying a characteristic color contained in an image, which is expressed by the received first color image data, according to a predetermined criterion; a relationship-of-correspondence establishment step of shifting the positions of lattice points, which fall into the domain in the color space expressing the identified characteristic color, so as to narrow the spacing between adjoining ones of the lattice points, and establishing the relationship of correspondence for each of the shifted lattice points; an image data conversion step of allocating a point of coordinates represented by first color image data to any of lattice points surrounding the point of coordinates according to a predetermined rule, and reading second color image data associated with the allocated lattice point so as to thus achieve the conversion; and a printing control step of executing printing according to the second color image data resulting from the conversion.

Consequently, a high-quality image having the markedness in the granulation of dots prevented is formed in a printout produced based on image data expressing a characteristic color or a color similar to the characteristic color.

Moreover, needless to say, the constituent features of the printing control method can be adapted to a printing control system or a printing control program according to the present invention.

Specifically, if the constituent features are adapted to a printing control program product, the printing control program product causes a computer to establish for each of lattice points in a predetermined color space the relationship of correspondence between first color image data employed in first image equipment and second color image data employed in second image equipment, and to reference the established relationships of correspondence so as to convert the first color image data into the second color image data. The printing control program product includes: a functional code that identifies a characteristic color contained in an image, which is expressed by received first color image data, according to a predetermined criterion; a functional code that shifts the positions of lattice points, which fall into the domain in the color space expressing the identified characteristic color, so as to narrow the spacing between adjoining ones of the lattice points, and that establishes the relationship of correspondence for each of the shifted lattice points; a functional code that allocates a point of coordinates represented by first color image data to any of lattice points surrounding the point of coordinates, according to a predetermined rule, and that reads second color image data associated with the allocated lattice point so as to thus achieve conversion; and a functional code that executes printing according to the second color image data resulting from the conversion.

Furthermore, a color conversion table employed in the aspects of the present invention will prove valuable because it enables conversion into second color image data that can effectively prevent the degradation in granularity of dots constituting a printout. The color conversion table specifies for each of lattice points in a predetermined color space the relationship of correspondence between first color image data employed in first image equipment and second color image data employed in second image equipment. The color conversion table is produced by executing a characteristic color recognition step of identifying a characteristic color, which is contained in an image expressed by received first color image data, according to a predetermined criterion, and a relationship-of-correspondence establishment step of shifting the positions of lattice points, which fall into the domain in the color space expressing the identified characteristic color, so as to narrow the spacing between adjoining ones of the lattice points, and establishing the relationship of correspondence for each of the shifted lattice points.

### BRIEF DESCRIPTION OF THE DRAWINGS

Embodiments of the present invention will be described in detail based on the following figures, wherein:

FIG. 1 is a block diagram showing the configuration of a computer or the like that implements a color conversion method;

FIG. 2 is an explanatory diagram showing a color conversion lookup table;

FIG. 3 is a flowchart describing reconstruction of the color conversion lookup table;

FIG. 4 shows part of an ab plane;

FIG. 5 shows a frequency distribution of values represented by each color data; and

FIG. 6 is an explanatory diagram showing part of a color space having the positions of lattice points thereof shifted and having lattice points thereof associated with items of a color conversion lookup table.

### DESCRIPTION OF THE PREFERRED EMBODIMENTS

Embodiments of the present invention will be described below by orderly taking up the following subjects:

### (1) Overview of Printing

### (2) Reconstruction of a Color Conversion Lookup Table

### (3) Other Embodiments

### (1) Overview of Printing

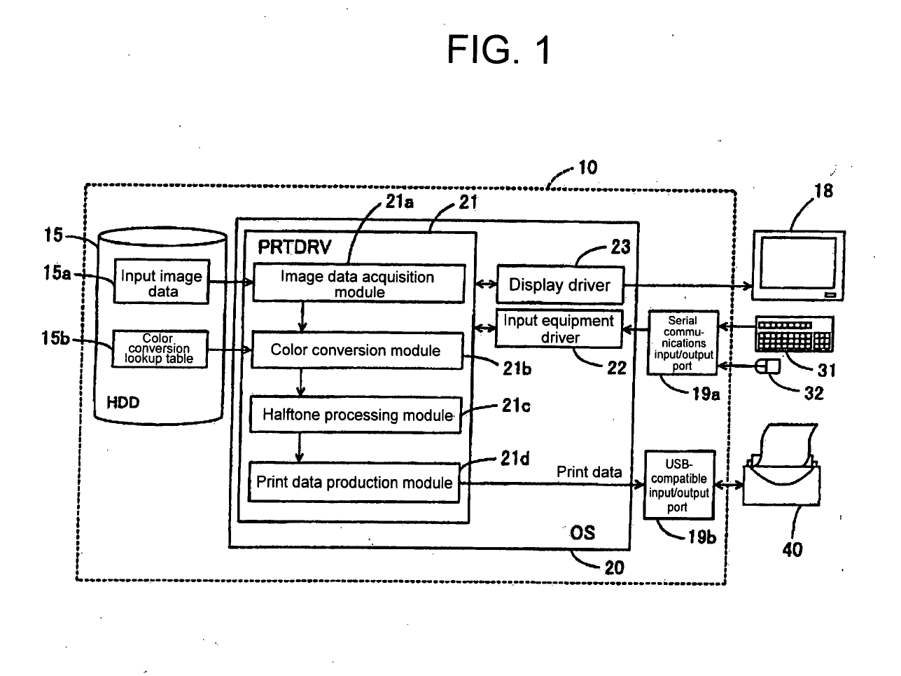

FIG. 1 shows the outline configuration of a computer or the like capable of implementing a color conversion method in accordance with the present invention. A computer 10 includes a CPU that is not shown but plays a pivotal role in performing arithmetic and logical operations, and a ROM and a RAM serving as storage media. The computer 10 makes the most of peripheral equipment such as a hard disk drive (HDD) 15 so as to run predetermined programs. Operating input equipment including a keyboard 31 and a mouse 32 is connected to the computer 10 via a serial communications input/output port 19a. A display 18 for displaying images or the like is connected to the computer 10 via a video capture board that is not shown. Furthermore, the computer 10 is connected to a printer 40 via a USB-compatible input/output port 19b. Namely, the computer 10 works as a printing control system when used in combination with the printer 40. The contents of processing to be performed by the computer 10 serving as the printing control system will be outlined below.

The printer 40 has a mechanism to or from which ink cartridges filled with respective color inks are attached or detached color by color. According to the present embodiment, cartridges filled with inks of cyan (C), magenta (M), yellow (Y), black (K), light cyan (lc), and light magenta (lm) are mounted in the printer 40. The printer 40 can create numerous colors by combining these inks, whereby a color image is formed on a printing medium. The printer 40 is an ink-jet printer. In addition to the ink-jet printer, the present invention can be applied to a laser printer and other various types of printers.

The computer 10 has a printer driver (PRTDRV) 21, an input equipment driver (DRV) 22, and a display driver (DRV) 23 installed in an operating system (OS) 20. The display driver 23 controls display of an image to be printed on the display 18 or display of a property screen image concerning the printer 40. The input equipment driver 22 receives a code signal from the keyboard 31 or mouse 32 via the serial communications input/output port 19a, and permits predetermined entering.

The printer driver 21 performs predetermined image processing on an image whose printing is instructed by an application program that is not shown, and executes printing. The printer driver 21 includes an image data acquisition module 21a, a color conversion module 21b, a halftone processing module 21c, and a print data production module 21d for the purpose of printing.

When printing is instructed, the printer driver 21 is driven. The printer driver 21 transmits data to the display driver 23 so that a user interface (UI) screen image through which a user is prompted to enter information on a printing medium to be used for printing, and information on conditions for printing including a printing speed will be displayed on the display. When the user manipulates the keyboard 31 or mouse 32 so as to enter required conditions for printing through the user interface screen image, the modules included in the printer driver 21 are started. The modules process pixels constituting input image data 15a (first color image data), whereby print data is produced. The produced print data is transmitted to the printer 40 via the USB-compatible input/output port 19b. The printer 40 then performs printing according to the print data.

To be more specific, the image data acquisition module 21a acquires the input image data 15a, which expresses an image whose printing has been instructed, from the hard disk drive 15. At this time, if necessary, predetermined resolution conversion is performed on the input image data 15a. The input image data 15a is dot-matrix data that expresses the color of each pixel by indicating the tones of primary colors of red (R), green (G), and blue (B) on a multilevel gray scale-and that is produced according to a calorimetric system conformable to the sRGB standards. Alternatively, JPEG image data produced based on an YCbCr calorimetric system, image data produced based on a CMYK colorimetric system, or any other various kinds of data can be adopted.

The color conversion module 21b converts a calorimetric system, according to which the color of each pixel is determined, from one to another. Fundamentally, a color conversion lookup table 15b recorded in the hard disk drive 15 is referenced in order to convert the input image data 15a (RGB data) into ink data (second color image data) that represents pixel by pixel gray levels of cyan, magenta, yellow, black, light cyan, and light magenta respectively. The ink data signifies magnitudes of recording by respective inks. A description will be made on the assumption that the tones of red, green, and blue or the tones of cyan, magenta, yellow, black, light cyan, and light magenta are each indicated on a gray scale having 256 gray levels from 0 to 255. Alternatively, a gray scale having 1024 gray levels may be adopted. According to the present embodiment, the color conversion module 21b performs preconversion to achieve color conversion.

After the color conversion module 21b has completed color conversion to produce ink data, the halftone processing module 21c converts the ink data into halftone data, which specifies for each pixel whether each of cyan, magenta, yellow, black, light cyan, and light magenta inks should be jetted or not, according to a known technique such as an error diffusion technique or a dither technique. Specifically, the halftone processing module 21c determines for each pixel whether the printer 40 should jet droplets of inks. The print data production module 21d receives halftone data items, sorts the data items in order of being used by the printer 40, and sequentially transmits the data items, which are required for one main scan, to the printer 40. The printer 40 has an ink-jet nozzle array incorporated as an ink-jet device therein. The nozzle array has plural ink-jet nozzles juxtaposed in a direction of sub-scan. Therefore, data items expressing several dots to be lined in the direction of sub-scan are used simultaneously. Among data items expressing dots lined in the direction of main scan, data items to be used simultaneously are sorted so that they will be simultaneously buffered in the printer 40 in order to produce print data. The print data is then transmitted to the printer 40 via the USB-compatible input/output port 19b. After all data items used to form an image by the printer 40 have been transferred, the printer 40 forms an image on a printing medium.

According to the present embodiment, color conversion including preconversion is performed. The color conversion including preconversion will be described below.

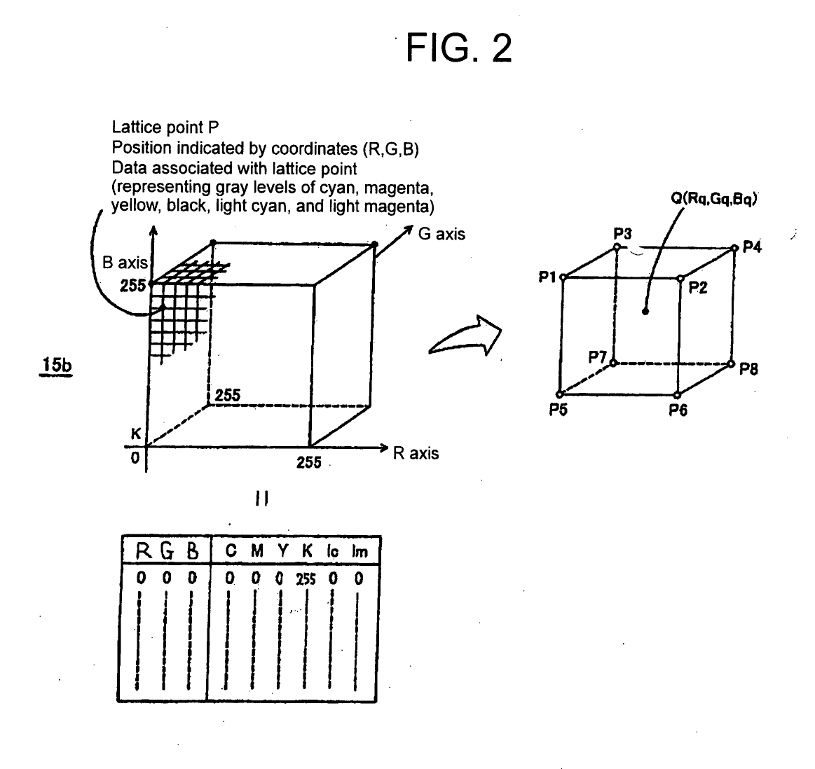

FIG. 2 shows the color conversion lookup table 15b. The color conversion lookup table 15b is an information table that specifies for each of lattice points P the relationship of correspondence between gray levels of red, green, and blue respectively and gray levels of cyan, magenta, yellow, black, light cyan, and light magenta respectively. The color conversion lookup table 15b has items thereof associated with numerous lattice points P(R,G,B) each of which is identified with coordinates representing the gray levels of red, green, and blue respectively and which are designated by substantially equidistantly dividing an RGB color space, which is defined with axes of coordinates indicating the gray levels of respective primary colors expressed by color data items constituting the input image data 15a, in the form of a lattice. The gray levels of cyan, magenta, yellow, black, light cyan, and light magenta respectively are recorded in the conversion lookup table 15b in association with each of the lattice points P. Assuming that seventeen lattice points are equidistantly designated on each of the axes of coordinates representing the gray levels of red, green, and blue respectively, the number of lattice points in the RGB color space associated with the items of the color conversion lookup table 15b is provided, for example, as 17<SUP>3</SUP>.

The color conversion module 21b references the color conversion lookup table 15b so as to perform color conversion including preconversion. In this case, a point Q of coordinates represented by the input image data 15a is allocated to any of eight lattice points P1 to P8 surrounding the point Q of coordinates. A description will proceed in conjunction with the right part of FIG. 2 showing one cubic lattice space. First, if the coordinates of the point Q (gray levels of red, green, and blue respectively) agree with the coordinates of any of the lattice points P1 to P8, the coordinates of the point Q are left intact. If the coordinates of the point Q disagree with the coordinates of all lattice points P1 to P8, the distance dn of the point Q of coordinates to each of the lattice points P1 to P8 is calculated. Assuming that the coordinates of the point Q in the RGB color space are coordinates (Rq,Gq,Bq) and the coordinates of the eight lattice points P1 to P8 therein are coordinates (R1,G1,B1) to (R8,G8,B8), the distance dn of the point Q of coordinates to each of the lattice points P1 to P8 is provided as {(Rn-Rq)<SUP>2</SUP>+(Gn-Gq)<SUP>2</SUP>+(Bn-Bq)<SUP>2</SUP>}<SUP>½</SUP>. The coordinates of the point Q are replaced with the coordinates of any of the lattice points P1 to P8 at a probability corresponding to a reciprocal ratio (1/dn) of the calculated distance. Specifically, the point Q of coordinates is allocated to a lattice point P, of which distance to the point Q is the shortest among all the lattice points P1 to P8, at the highest probability. The point Q of coordinates is allocated to a lattice point P, of which distance to the point Q is far, at a low probability.

The replaced coordinates are specified in the color conversion lookup table 15b. The coordinates representing the gray levels of cyan, magenta, yellow, black, light cyan, and light magenta respectively are read from the color conversion lookup table 15 in association with the replaced coordinates. In this way, the input image data 15a is converted into the ink data in terms of colors.

As mentioned above, color conversion including preconversion provides coordinates, which result from conversion, by merely forcibly allocating a point Q of coordinates to any of surrounding lattice points P. Compared with color conversion employing linear interpolation such as so-called tetrahedral interpolation, the processing time is much shorter.

On the other hand, a point of coordinates represented by the input image data 15a may be allocated to a lattice point P whose coordinates express a color that is inconsistent with a color expressed by the input image data 15a. Moreover, the number of lattice points to any of which the point of coordinates is allocated is limited. Therefore, the precision in color conversion cannot help being lower than the precision in color conversion employing linear interpolation. The disadvantage of the color conversion including preconversion is that the granulation of dots in a printout is likely to become discernible. If the color conversion including preconversion is adopted as a color conversion technique, the narrower the spacing between adjoining ones of lattice points associated with the items of the color conversion lookup table 15b is, the higher the precision in color conversion is. Consequently, the granulation of dots in a printout becomes indiscernible. In contrast, the wider spacing between adjoining ones of the lattice points leads to the discernible granulation of dots in a printout.

According to the present invention, as described below, a color conversion lookup table is reconstructed in association with lattice points whose positions are optimized according to an image to be printed. Consequently, while the advantage of fast calculations resulting from adoption of the color conversion including preconversion is maintained, the degradation in the granularity of dots in a printout is prevented.

### (2) Reconstruction of a Color Conversion Lookup Table

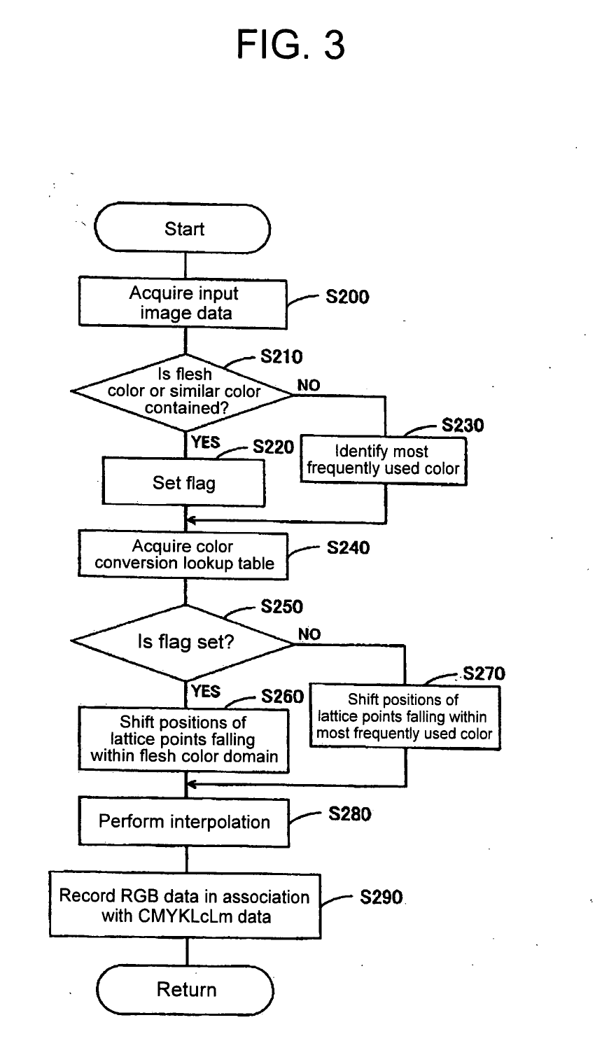

FIG. 3 is a flowchart describing reconstruction of a color conversion lookup table employed in the present invention. When the printer driver 21 executes a printing control procedure for any input image data 15a, by the image data acquisition module 21a and the color conversion module 21b are mainly engaged in the reconstruction. Therefore, the image data acquisition module 21a and the color conversion module 21b correspond to a characteristic color recognition processor and a relationship-of-correspondence establishment processor.

At step S200, the printer driver 21 first acquires input image data 15a from the hard disk drive 15.

At step S210, the printer driver 21 checks an image to be printed to see if it contains a flesh color or a similar color (flesh color identification). The flesh color or a similar color is a color of dots whose granulation should appear indiscernible in a photographic image or the like of a human being. If the presence of the flesh color or a similar color is recognized through flesh color identification, the flesh color or a similar color is adopted as a characteristic color and taken into consideration during reconstruction of a lookup table later.

Flesh color identification can be achieved according to various methods because an image to be printed is merely checked to see if it contains the flesh color or a similar color. In the present embodiment, for example, a distribution of values represented by the input image data 15a in an L<SUP>*</SUP>a<SUP>*</SUP>b<SUP>*</SUP> color space (defined by the International Committee on Illumination) (hereinafter, <SUP>*</SUP> will be omitted) is checked to see if the flesh color or a similar color is contained.

Since the input image data 15a is, as mentioned above, RGB data, each of pixels constituting the input image data 15a is converted into coordinates defined in the Lab color space (Lab data) according to a predetermined conversion formula. Image data conformable to the sRGB standards is converted into coordinates defined in the Lab color space according to a known conversion formula.

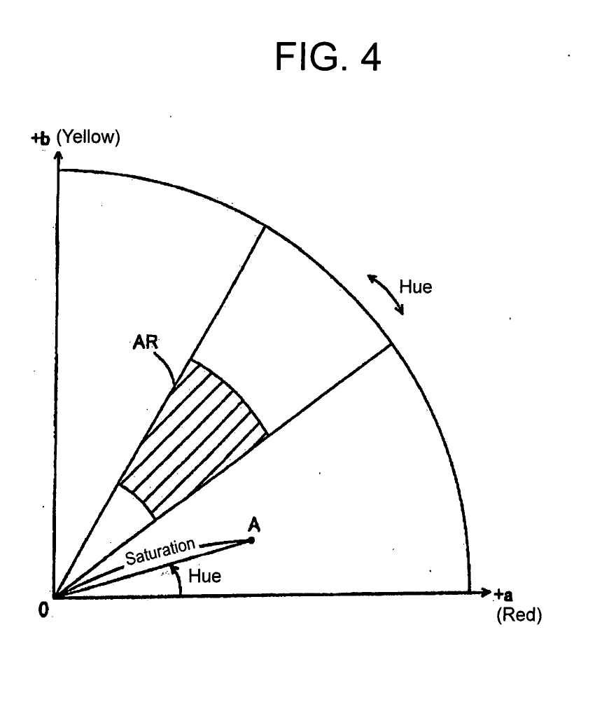

FIG. 4 shows part of an ab plane in the Lab color space.

On the ab plane, a point A of coordinates resulting from conversion of RGB data that is input image data 15a expressing a certain pixel is plotted. On the ab plane, the distance from the origin o to a point of coordinates indicates a saturation. An +a axis indicates 0°, and an angle at which a counterclockwise direction meets the +a axis indicates a hue. In FIG. 4, a flesh color domain AR is hatched. Namely, on the ab plane, the flesh color and similar colors are indicated with a predetermined range of hues between red (+a axis) and yellow (+b axis). The flesh color domain AR having a predetermined area within the range of hues is designated in the computer 10 in advance.

During flesh color identification, the number of points of coordinates resulting from conversion of the input image data 15a and falling within the flesh color domain AR is counted and checked to see if it exceeds a predetermined threshold. The threshold may be determined as a ratio to the sum total of pixels constituting the input image data 15a or may be held in the printer driver 21 as a fixed value in advance. Otherwise, a user may be able to designate a certain value.

If the number of counted points of coordinates exceeds the threshold, the presence of the flesh color or a similar color in the image to be printed is recognized. A flag fg indicating the presence of the flesh color or a similar color is set to 1, and control is passed to the next processing (step S220). Whether the flag is set or not is referenced when positions of lattice points are shifted later.

If the number of counted points of coordinates does not exceed the threshold, the absence of the flesh color or a similar color from the image to be printed is recognized or the unnoticeable presence thereof is recognized. The printer driver 21 identifies a color that is most frequently used in an image expressed by the input image data 15a (step S230). The most frequently used color is identified based on frequency distributions of gray levels of red, green, and blue represented by color data items constituting the input image data 15a.

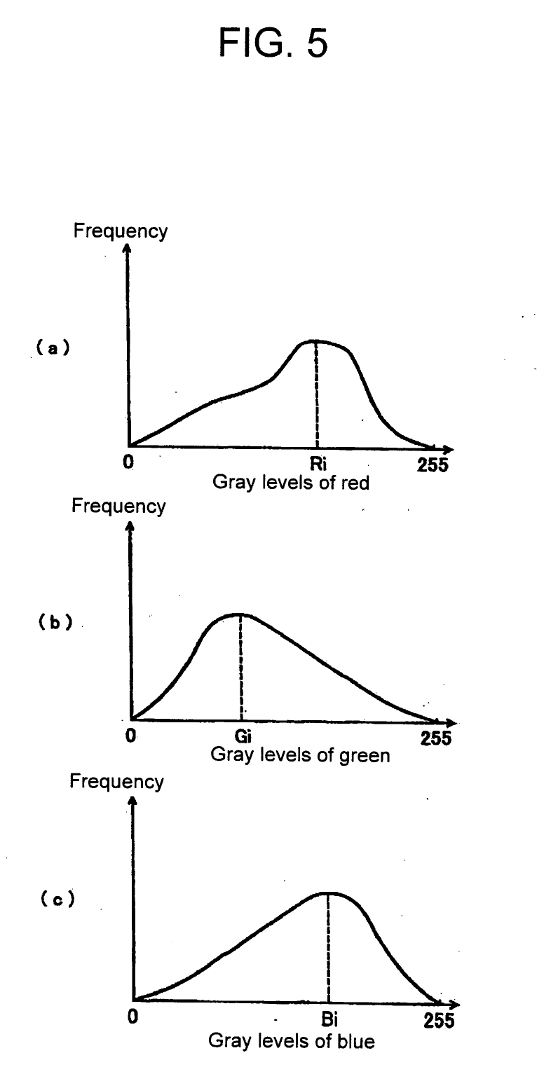

FIG. 5(a) to FIG. 5(c) show examples of the frequency distribution of gray levels of red, green, or blue. The printer driver 21 detects the most frequently used gray levels Ri, Gi, and Bi that are gray levels whose frequencies are the highest in the respective frequency distributions. A color expressed by RGB data representing the detected most frequently used gray levels (Ri,Gi,Bi) is identified as the most frequently used color. However, a mean or a median may be detected from each of the frequency distributions instead of the most frequently used gray level. A color deriving from the gray levels of the means or medians may be adopted as the most frequently used color. The thus identified most frequently used color is adopted as a characteristic color of an image expressed by the input image data 15a.

After the characteristic color of an image to be printed has been identified, the printer driver 21 acquires the color conversion lookup table 15b from the hard disk drive 15 at step S240.

Thereafter, at step S250, the flag fg is checked to see if it is set to 1. If the flag fg is set to 1, the positions of lattice points that fall into the domain in the RGB color space which expresses a flesh color and similar colors, and that are associated with items included in the color conversion lookup table 15b are shifted in order to narrow the spacing between adjoining ones of the lattice points (step S260). In other words, since the image to be printed contains the flesh color or a similar color to a predetermined degree, the positions of lattice points associated with items of the color conversion lookup table 15b are optimized in order to improve the precision in converting the flesh color or a similar color.

To be more specific, a point Pj of coordinates in the RGB space expressing a flesh color is identified. The positions of lattice points surrounding the point Pj of coordinates and being associated with items of the color conversion lookup table 15b are shifted in order to narrow the spacing between adjoining ones of the lattice points. The point Pj of coordinates is, for example, identified by calculating a mean of Lab data items that are produced by converting pixels of the input image data 15a and that fall into the flesh-color domain AR shown in FIG. 4, and interpolating RGB data associated with the Lab data of the mean using RGB data items associated with the Lab data items. Otherwise, a mean of Lab data items representing coordinates that indicate mutually closely plotted points may be calculated, and a point of coordinates represented by RGB data associated with the mean may be adopted as the point of coordinates Pj. Otherwise, RGB data expressing a flesh color may be recorded in the printer driver 21 as the coordinates indicating the point Pj of coordinates.

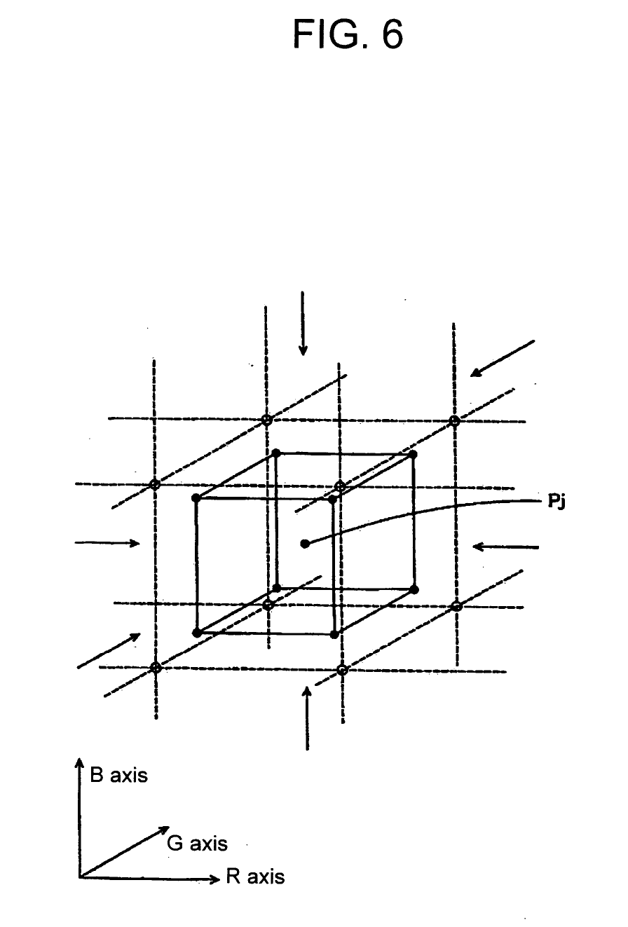

FIG. 6 shows a state in which the positions of lattice points surrounding the point Pj of coordinates and being associated with items of the color conversion lookup table 15b are shifted (rearranged) in order to narrow the spacing between adjoining ones of the lattice points. FIG. 6 shows only the lattice points surrounding the point Pj of coordinates. The spacing between adjoining ones of the lattice points that are not shifted is inferred from dashed lines, and the spacing between adjoining ones of the shifted lattice points is inferred from solid lines. The positions of lattice points may be shifted in various manners. In the drawing, the spacing between adjoining ones of lattice points surrounding the point Pj of coordinates is narrowed in the directions of all the three axes of the RGB color space. Alternatively, the spacing between adjoining ones may be narrowed in the direction of only one axis thereof or in the directions of two axes thereof. Moreover, the positions of all lattice points arranged equidistantly on a gray scale from level 0 to level 255 are shifted, and the positions of lattice points located near the point Pj of coordinates may be shifted by a long distance or the positions of only lattice points falling within a predetermined range surrounding the point Pj of coordinates may be shifted in order to shorten the distances of the lattice points to the point Pj of coordinates.

If the flag fg is not recognized at step S250 to be set to 1, the printer driver 21 shifts the positions of lattice points associated with items of the color conversion lookup table 15b in order to narrow the spacing between adjoining ones of the lattice points surrounding a point of coordinates represented by RGB data expressing the characteristic color (most frequently used color) identified at step S230 (step S270). The positions of lattice points may be shifted in various manners. Fundamentally, the aforesaid manners may be adopted.

At step S280, the printer driver 21 interpolates gray levels of cyan (C), magenta (M), yellow (Y), black (K), light cyan (lc), and light magenta (lm) associated with coordinates (representing gray levels of red, green, and blue) indicating each of the shifted lattice points. Specifically, CMYKlclm data items recorded in association with RGB data items prior to shifting is referenced or used to linearly interpolate CMYKlclm data associated with RGB data representing coordinates of a shifted point.

At step S290, RGB data items indicating the shifted positions of lattice points are recorded in association with CMYKlclm data items that are interpolated at step S280. Thus, the reconstruction of the color conversion lookup table 15b is completed.

The color conversion module 21b references the reconstructed color conversion lookup table 15b so as to perform the color conversion including preconversion. Namely, the input image data 15a is converted into ink data that represents gray levels of cyan, magenta, yellow, black, light cyan, and light magenta respectively on the gray scale of 256 gray levels. Thereafter, the halftone processing module 21c performs halftone processing on the ink data, and the print data production module 21d produces print data from the halftone data. The printer 40 performs printing according to the print data.

As mentioned above, if an image to be printed contains a flesh color or a similar color, the color conversion lookup table 15b is reconstructed so that items thereof will be associated with lattice points which falls within a flesh color domain and which are mutually closely rearranged. If the image to be printed does not contain the flesh color or a similar color or if the image to be printed contains the flesh color or a similar color to such an extent that the color plays a minor role in the image, the color conversion lookup table 15b is reconstructed so that items thereof will be associated with lattice points which fall into a color domain centered on a point expressing a color identified as a color most frequently used in the image and which are mutually closely rearranged. The reconstructed color conversion lookup table 15b is used to perform the color conversion including preconversion. This improves the precision in color conversion of image data expressing a characteristic color, that is, the flesh color or a similar color used to depict a human face or a color most frequently used in an image. The change in ink data between adjoining pixels is smoothened. Consequently, the granularity of dots of colors that should appear little granularly in an image is improved. This results in a high-quality printout.

Moreover, according to the present invention, among the limited lattice points associated with the items of the color conversion lookup table 15b, lattice points that fall into a color domain expressing colors which are colors of dots that should appear little granularly are mutually closely rearranged. Therefore, the degradation in the granularity of dots in a printout can be effectively prevented without an increase in the number of lattice points. Compared with a case where the number of lattice points is largely increased in order to prevent the degradation, the number of calculations needed to reconstruct a lookup table is limited and the data size of the lookup table is small. The consumption of a storage area in which the lookup table is stored is therefore limited.

### (3) Other Embodiments

Identification of a characteristic color of each image is not limited to the foregoing one but may be performed as described below. Namely, the printer driver 21 may read header information appended to the input image data 15a so as to identify the characteristic color of an image expressed by the input image data. For example, if the input image data 15a conforms to such standards as the Print Image Matching (PIM is a registered trademark granted to Seiko Epson Corp.) or the Exif2.2 (Exif is a registered trademark granted to the Japan Electronics and Information Technology Industries Association), information on an imaged scene is recorded as the header information. If the imaged scene is set to a human being, the characteristic color is recognized as a flesh color. Thus, the characteristic color is recognized based on the header information at step S210. If the imaged scene is set to a human being, the flag fg is set to 1 at step S220. Consequently, the color conversion lookup table 15b is reconstructed according to the characteristic of an image.

Moreover, the printer driver 21 may have a so-called face recognition facility, that is, a facility of checking an image expressed by the input image data 15a to see if it shows a human face. The characteristic color of an image may be recognized based on the results of the verification achieved by the face recognition facility. In this case, at step S210, the face recognition facility checks an image to see if it shows a human face. If the image shows a human face, the characteristic color of the image is recognized as the flesh color, and the flag fg is set to 1 at step S220. Thus, the color conversion lookup table 15b is reconstructed according to the characteristic of an image.

The foregoing invention has been described in terms of preferred embodiments. However, those skilled, in the art will recognize that many variations of such embodiments exist. Such variations are intended to be within the scope of the present invention and the appended claims.

What is claimed is:

1. A color conversion method in which the relationship of correspondence between first color image data employed in first image equipment and second color image data employed in second image equipment is established for each of lattice points in a predetermined color space, and the established relationships of correspondence are referenced so as to convert the first color image data into the second color image data, comprising:
a characteristic color recognition step of identifying a characteristic color contained in an image expressed by the received first color image data according to a predetermined criterion;
a relationship-of-correspondence establishment step of shifting the positions of lattice points, which fall into the domain in the color space expressing the identified characteristic color, so as to narrow the spacing between adjoining ones of the lattice points, and establishing the relationship of correspondence for each of the shifted lattice points; and
an image data conversion step of allocating a point of coordinates represented by first color image data to any of lattice points surrounding the point of coordinates according to a predetermined rule, and reading second color image data associated with the allocated lattice point so as to thus achieve conversion.

2. The color conversion method according to claim 1, wherein: at the characteristic color recognition step, the image expressed by the received first color image data is checked to see if it contains the color expressed by a predetermined color domain; and if the image contains the color expressed by the color domain, the predetermined color expressed by the color domain is recognized as the characteristic color of the image expressed by the first color image data.

3. The color conversion method according to claim 2, wherein at the characteristic color recognition step, the image is checked to see if it contains the color expressed by a predetermined flesh color domain.

4. The color conversion method according to claim 1, wherein at the characteristic color recognition step, a color highly frequently used in the image expressed by the received first color image data is identified and recognized as the characteristic color of the image expressed by the first color image data.

5. The color conversion method according to claim 4, wherein at the characteristic color recognition step, a frequency distribution is produced using each of color data items constituting the first color data, that is, each of color data items constituting the first color image data, and the highly frequently used color is identified based on the produced frequency distributions.

6. The color conversion method according to claim 5, wherein at the characteristic color recognition step, a color expressed by the substantial medians of the frequency distributions produced based on respective color data items is recognized as the highly frequently used color.

7. A color conversion system that establishes for each of lattice points in a predetermined color space the relationship of correspondence between first color image data employed in first image equipment and second color image data employed in second image equipment, and references the established relationships of correspondence so as to convert the first color image data into the second color image data, comprising:
a characteristic color recognition processor that identifies a characteristic color contained in an image expressed by the received first color image data according to a predetermined criterion;
a relationship-of-correspondence establishment processor that shifts the positions of lattice points, which fall into the domain in the color space expressing the identified characteristic color, so as to narrow the spacing between adjoining ones of the lattice points, and establishes the relationship of correspondence for each of the shifted lattice points; and
an image data conversion processor that allocates a point of coordinates represented by first color image data to any of lattice points surrounding the point of coordinates according to a predetermined rule, and reads second color image data associated with the allocated lattice point so as to thus achieve conversion.

8. A color conversion program product that causes a computer to establish for each of lattice points in a predetermined color space the relationship of correspondence between first color image data employed in first image equipment and second color image data employed in second image equipment, and to reference the established relationships of correspondence so as to convert the first color image data into the second color image data, comprising:
a functional code that identifies a characteristic color contained in an image expressed by the received first color image data according to a predetermined criterion;
a functional code that shifts the positions of lattice points, which fall into the domain in the color space expressing the identified characteristic color, so as to narrow the spacing between adjoining ones of the lattice points, and establishes the relationship of correspondence for each of the shifted lattice points; and
a functional code that allocates a point of coordinates represented by first color image data to any of lattice points surrounding the point of coordinates according to a predetermined rule, and reads second color image data associated with the allocated lattice point so as to thus achieve conversion.

9. A printing control method in which the relationship of correspondence between first color image data employed in first image equipment and second color image data employed in second image equipment is established for each of lattice points in a predetermined color space, and the established relationships of correspondence are referenced so as to convert the first color image data into the second color image data, comprising:
a characteristic color recognition step of identifying a characteristic color contained in an image expressed by the received first color image data according to a predetermined criterion;
a relationship-of-correspondence establishment step of shifting the positions of lattice points, which fall into the domain in the color space expressing the identified characteristic color, so as to narrow the spacing between adjoining ones of the lattice points, and establishing the relationship of correspondence for each of the shifted lattice points;
an image data conversion step of allocating a point of coordinates represented by first color image data to any of lattice points surrounding the point of coordinates according to a predetermined rule, and reading second color image data associated with the allocated lattice point so as to thus achieve conversion; and
a printing control step of executing printing according to the second color image data resulting from the conversion.

10. A printing control system that establishes for each of lattice points in a predetermined color space the relationship of correspondence between first color image data employed in first image equipment and second color image data employed in second image equipment, and references the established relationships of correspondence so as to convert the first color image data into the second color image data, comprising:
a characteristic color recognition processor that identifies a characteristic color contained in an image expressed by the received first color image data according to a predetermined criterion;
a relationship-of-correspondence establishment processor that shifts the positions of lattice points, which fall into the domain in the color space expressing the identified characteristic color, so as to narrow the spacing between adjoining ones of the lattice points, and establishes the relationship of correspondence for each of the shifted lattice points;
an image data conversion processor that allocates a point of coordinates represented by first color image data to any of lattice points surrounding the point of coordinates according to a predetermined rule, and reads second color image data associated with the allocated lattice point so as to thus achieve conversion; and
a printing control processor that executes printing according to the second color image data resulting from the conversion.

11. A printing control program product that causes a computer to establish for each of lattice points in a predetermined color space the relationship of correspondence between first color image data employed in first image equipment and second color image data employed in second image equipment, and to reference the established relationships of correspondence so as to convert the first color image data into the second color image data, comprising:
a functional code that identifies a characteristic color contained in an image expressed by the received first color image data according to a predetermined criterion;
a functional code that shifts the positions of lattice points, which fall into the domain in the color space expressing the identified characteristic color, so as to narrow the spacing between adjoining ones of the lattice points, and establishes the relationship of correspondence for each of the shifted lattice points;
a functional code that allocates a point of coordinates represented by first color image data to any of lattice points surrounding the point of coordinates according to a predetermined rule, and reads second color image data associated with the allocated lattice point so as to thus achieve conversion; and
a functional code that executes printing according to the second color image data resulting from the conversion.

12. A color conversion table that specifies for each of lattice points in a predetermined color space the relationship of correspondence between first color image data employed in first image equipment and second color image data employed in second image equipment, and that is produced by executing:
a characteristic color recognition step of identifying a characteristic color contained in an image expressed by the received first color image data according to a predetermined criterion; and
a relationship-of-correspondence establishment step of shifting the positions of lattice points, which fall into the domain in the color space expressing the identified characteristic color, so as to narrow the spacing between adjoining ones of the lattice points, and establishing the relationship of correspondence for each of the shifted lattice points.
